(19) United States
(12) Patent Application Publication
(10) Pub. No.: US 2006/0039116 A1
(43) Pub. Date: Feb. 23, 2006

(54) Heat-sinking base plate and its manufacturing method

(75) Inventor: Wan-Tien Chen, Taipei (TW)

Correspondence Address: DENNISON, SCHULTZ, DOUGHERTY & MACDONALD, SUITE 105, 1727 KING STREET, ALEXANDRIA, VA, 22314-2700, US

(73) Assignee: EGBON ELECTRONICS LTD.

(21) Appl. No.: 10/909,372

(22) Filed: Aug. 3, 2004

(51) Int. Cl. H05K 7/20

(52) U.S. Cl. 361/705

(57) ABSTRACT

A heat-sinking base plate and its manufacturing method, there are a plastic non-metallic substrate and a heat conductive layer; the substrate has thereon a plurality of micro holes, the heat conductive layer contains a layer of metallic heat conductive coating, the heat conductive layer is applied on the outer surface of the substrate and is filled in the micro holes of the substrate, thereby the substrate is heat conductive, so heat energy can be transferred from one side to the other side of the substrate through the heat conductive layer in the micro holes, and the substrate has an excellent heat-sinking effect.

### BACKGROUND OF THE INVENTION

1. Field of the Invention

The present invention is related to a heat-sinking base plate and its manufacturing method; and especially related to a heat-sinking base plate having on its substrate a heat conductive layer, so that heat energy can be transferred from one side to the other side of the substrate, and related to the manufacturing method of the base plate. The structure of the base plate is simple and manufacturing of it is easy and costs low; it can effectively transfer and scatter the accumulated heat after assembling, and is suitable to be used as a covering housing of a heating module of a personal computer, a notebook, a PDA or a cell phone etc.

2. Description of the Prior Art

In the modern age with swift advancing science and technology, various electronic products such as personal computers, notebooks, PDA's or cell phones etc. have been the necessities in the human life. No matter we are on our working posts or in our family lives, the time of using electronic products have been tending to increase from day to day.

By the fact that electronic products keep on being changed to “light, thin and small”, this gets a result that the preciseness and sizes of various elements and processing equipments have been being severely required from day to day. Among the various electronic products, the goal of designing covering housings not only is to protect the structures of the products themselves and provide the good appearance for attracting customers to be interested in purchasing, but also to reach another goal of heat sinking.

Taking a notebook as an example, quite many consumers consider about the factors of the main frequency of a CPU, the capacity of a hard disk, the size of a displaying screen etc. during purchasing the notebook. They do not pay attention to the importance of the material of a covering housing. Because the notebook is compact inside, the CPU, the hard disk and the main board are all elements that generate heat, if the heat accumulated therein can not be scattered in time, the computer will be down, and even will damage the interior elements if the situation is serious. Whether the housing of the notebook can fast make heat sinking is also an important factor in selecting material therefor.

The materials of covering housings of notebooks mostly are magnesium-aluminum alloys. In fact, magnesium-aluminum alloys are not very solid, high in price, heavy by weight and have limited effect of heat sinking. After using for long period of time, the original silver-white color will be worn out to reveal their proper dark gray color. If the alloys are scraped inadvertently, the scrapes will be very evident. To solve the problems that the magnesium-aluminum alloys encountered, manufacturers introduced space titanium metal in covering housings, but it is not popularly used because of the matter of cost.

### SUMMARY OF THE INVENTION

In view of the above mentioned defects of inconvenience in manufacturing with metal alloys and in using as well as inferiority of heat sinking, high cost, uneasiness of obtaining material and recovering etc., the inventor provides the present invention after nonstop study and improvement.

The primary object of the present invention is to provide a heat-sinking base plate being structurally simple, easy for manufacturing and cost low, which base plate can effectively transfer and scatter accumulated heat after assembling, and to provide a manufacturing method of the base plate.

To achieve the above object, in the heat-sinking base plate and the manufacturing method of the base plate of the present invention, there are a plastic non-metallic substrate and a heat conductive layer; the substrate has thereon a plurality of micro holes, the heat conductive layer contains a layer of metallic heat conductive coating, the heat conductive layer is applied on the outer surface of the substrate and is filled in the micro holes of the substrate, thereby the substrate is heat conductive, so heat energy can be transferred from one side to the other side of the substrate through the heat conductive layer in the micro holes, and the substrate has an excellent heat-sinking effect.

The present invention will be apparent after reading the detailed description of the preferred embodiments thereof in reference to the accompanying drawings.

### BRIEF DESCRIPTION OF THE DRAWINGS

FIG. 1 is a sectional view showing the appearance of a partial portion of a substrate of the embodiment of the present invention;

FIG. 2 is a sectional view showing the appearance of a partial portion of a heat-sinking base plate after connecting of the embodiment of the present invention;

FIG. 3 is a sectional view showing the appearance of the heat-sinking base plate after shaping of the embodiment of the present invention;

FIG. 4 is a flow chart of the manufacturing method of the heat-sinking base plate of the present invention;

FIG. 5 is a schematic view showing the state of use of the embodiment of the heat-sinking base plate of the present invention;

FIG. 6 is a schematic view showing the state of use of the embodiment of the heat-sinking base plate of the present invention in covering an electronic article.

### DETAILED DESCRIPTION OF THE PREFERRED EMBODIMENT

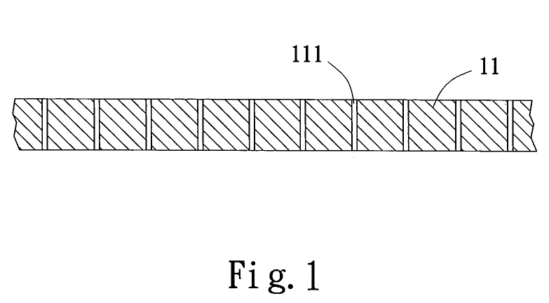

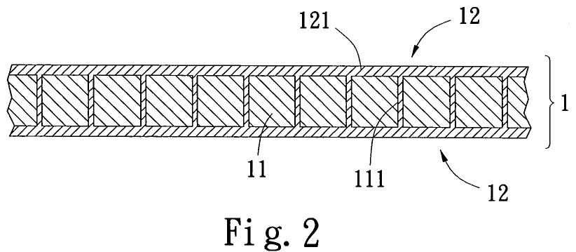

Referring to FIGS. 1 and 2 showing an embodiment of a heat-sinking base plate of the present invention and its method of manufacturing, wherein the heat-sinking base plate 1 is used as a covering housing for covering an electronic unit such as a personal computer, a notebook, a PDA or a cell phone etc., it is composed of a plastic non-metallic substrate 11 and a heat conductive layer 12.

The plastic non-metallic substrate 11 can be made of fiber glass (FRP) or one selected among polyethylene (HDPE, LDPE, LLDPE), polyethylene chloride, polypropyrene (PP), poly-propyrene copolymer (PPC), ethylene/vinyl acetate copolymer (EVA), polystyrene (PS), acrylonitrile/butylethylene/styrene copolymer (ABS), styrene/maleic anhydride copolymer, impact resistant polystyrene (HIPS), para-polyphthalic diethyl ester (PET) and polyvinyl chloride (PVC). The plastic non-metallic substrate 11 is provided thereon with a plurality of micro holes 111.

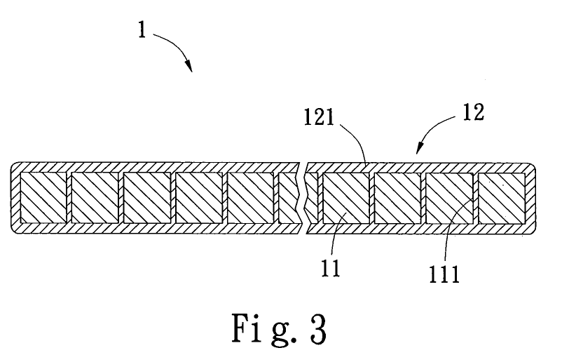

The heat conductive layer 12 is formed by applying a layer of metallic heat conductive coating 121 on the outer surface of the substrate 11. The mode of applying can be smearing or dipping etc. (such as are shown in FIGS. 2 and 3), so that the heat conductive layer 12 is filled in the micro holes 111.

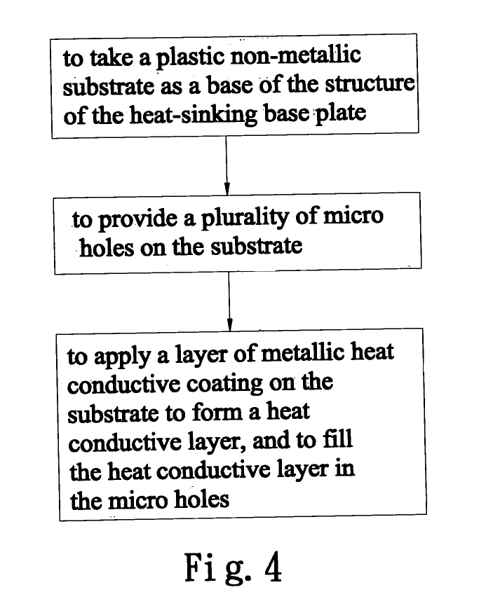

As shown in FIG. 4, the method of manufacturing of the heat-sinking base plate 1 includes the following steps:

a. to take a plastic non-metallic substrate 11 as a base of the structure of the heat-sinking base plate 1;

b. to provide a plurality of micro holes 111 on the substrate 11;

c. to apply a layer of metallic heat conductive coating 121 on the substrate 11 to form a heat conductive layer 12, and to fill the heat conductive layer 12 in the micro holes 111.

Referring to FIGS. 1-4, in practicing, the plastic non-metallic substrate 11 is taken as a base of the structure of the heat-sinking base plate 1, the material of the plastic non-metallic substrate 11 can be made of fiber glass (FRP) or one selected among polyethylene (HDPE, LDPE, LLDPE), polyethylene chloride, polypropyrene (PP), polypropyrene copolymer (PPC), ethylene/vinyl acetate copolymer (EVA), polystyrene (PS), acrylonitrile/butylethylene/styrene copolymer (ABS), styrene/maleic anhydride copolymer, impact resistant polystyrene (HIPS), para-polyphthalic diethyl ester (PET) and polyvinyl chloride (PVC); the plastic non-metallic substrate 11 is provided practically on most of the area thereof with a plurality of micro holes 111; and lastly, the heat conductive layer 12 is formed by applying a layer of metallic heat conductive coating 121 on the outer surface of the substrate 11, the heat conductive layer 12 is filled in the micro holes 111 (this process can be performed by the nanotechnology).

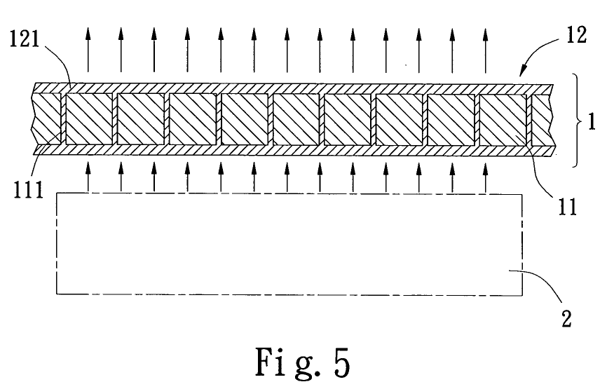

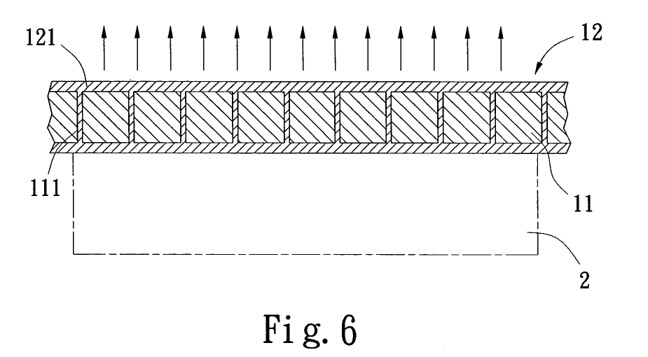

Thereby, when the heat-sinking base plate 1 of the present invention is used as a housing for covering an electronic unit 2 (such as are shown in FIGS. 5 and 6), heat generated by the electronic unit 2 can be transferred from one side of the substrate 11 applied with the heat conductive layer 12 through the micro holes 111 fully filled with the layer of metallic heat conductive coating 121 to the other side of the substrate 11 also with the heat conductive layer 12, thus fast and effective heat sinking can be achieved.

Therefore, the heat-sinking base plate and its method of manufacturing of the present invention has the following advantages:

1. The present invention takes plastic non-metallic material to make a substrate, it costs low, and its weight is smaller than that of a conventional metallic article; thereby, it is convenient for a consumer for manufacturing, recovering or using, and can reduce waste of metallic resources.

2. The present invention provides a plurality of micro holes on the substrate, so that heat energy can be transferred from one side of the substrate through the micro holes fully filled with a layer of metallic heat conductive coating to the other side of the substrate, and fast

1. A heat-sinking base plate comprising:
a plastic non-metallic substrate, said substrate has thereon a plurality of micro holes; and
a heat conductive layer containing a layer of heat conductive coating and, being applied on the outer surface of said substrate and filled in said micro holes of said substrate, thereby said layer of heat conductive coating applied on said outer surface of said substrate forms a heat conductive state.

2. The heat-sinking base plate as in claim 1, wherein, said layer of heat conductive coating is a layer of metallic coating.

3. The heat-sinking base plate as in claim 1, wherein, said layer of heat conductive coating is applied on said outer surface of said substrate in a mode of smearing.

4. The heat-sinking base plate as in claim 1, wherein, said plastic non-metallic substrate is made of one selected from among polyethylene (HDPE, LDPE, LLDPE), polyethylene chloride, polypropyrene (PP), poly-propyrene copolymer (PPC), ethylene/ vinyl acetate copolymer (EVA), polystyrene (PS), acrylonitrile /butylethylene/styrene copolymer (ABS), styrene/maleic anhydride copolymer, impact resistant polystyrene (HIPS), para-polyphthalic diethyl ester (PET) and polyvinyl chloride (PVC).

5. The heat-sinking base plate as in claim 1, wherein, said plastic non-metallic substrate is made of fiber glass (FRP).

6. A method of manufacturing a heat-sinking base plate, said method comprises the following steps:
a. to take a plastic non-metallic substrate as a base of the structure of said heat-sinking base plate;
b. to provide a plurality of micro holes on said substrate; and
c. to apply a layer of heat conductive coating on said substrate to form said heat conductive layer, and to fill said heat conductive layer in said micro holes.

7. The method of manufacturing a heat-sinking base plate as in claim 6, wherein, said layer of heat conductive coating is applied on an outer surface of said substrate in a mode of smearing.

8. The method of manufacturing a heat-sinking base plate as in claim 6, wherein, said heat conductive layer is formed by dipping said substrate in said layer of heat conductive coating.

9. The method of manufacturing a heat-sinking base plate as in claim 6, wherein: said plastic non-metallic substrate is made of one selected from among polyethylene (HDPE, LDPE, LLDPE), polyethylene chloride, polypropyrene (PP), poly-propyrene copolymer (PPC), ethylene/vinyl acetate copolymer (EVA), polystyrene (PS), acrylonitrile/butylethylene/styrene copolymer (ABS), styrene/maleic anhydride copolymer, impact resistant polystyrene (HIPS), para-polyphthalic diethyl ester (PET) and polyvinyl chloride (PVC).

10. The method of manufacturing a heat-sinking base plate as in claim 6, wherein, said layer of heat conductive coating is a layer of metallic coating.

11. A heat emitting unit using said heat-sinking base plate claimed in claim 1 as a housing thereof.

12. The heat emitting unit as in claim 11, said unit is a personal computer, a notebook, a PDA or a cell phone.
